(19) United States
(12) Patent Application Publication
(10) Pub. No.: US 2023/0288501 A1
(43) Pub. Date: Sep. 14, 2023

(54) ELECTRIC VEHICLE SUPPLY EQUIPMENT

(71) Applicant: Indra Renewable Technologies Ltd, Malvern (GB)

(72) Inventors: Michael SCHOOLING, Malvern (GB); Philip STRONG, Malvern (GB); Petros KOUNNOS, Malvern (GB)

(21) Appl. No.: 18/319,781

(22) Filed: May 18, 2023

Related U.S. Application Data
(63) Continuation of application No. PCT/EP2021/082187, filed on Nov. 18, 2021.

(30) Foreign Application Priority Data
Nov. 19, 2020 (GB) 2018231.7

(51) Int. Cl. G01R 31/69; G01R 31/52; B60L 53/62

(52) U.S. Cl. CPC G01R 31/69; G01R 31/52; B60L 53/62

(57) ABSTRACT

Electric vehicle supply equipment has a test circuit configured to be switchable from a first test mode to at least a second test mode. In the first test mode, the test circuit is configured to measure a first voltage difference between a live terminal and a neutral terminal, a second voltage difference between the live terminal and a reference ground terminal and a third voltage difference between a circuit protective conductor terminal and the reference ground terminal and to disconnect a charging supply if at least one of the first, second and third voltage differences exceeds a respective voltage limit. In the second test mode, the test circuit is configured to measure the first voltage difference and to disconnect the charging supply if the first voltage difference exceeds a respective voltage limit and not to disconnect the charging supply in response to any test of the second or third voltage differences. The voltage limit for the first voltage difference is configured to be greater in the first test mode than in the second test mode.

### CROSS-REFERENCE TO RELATED APPLICATIONS

This application is a continuation under 35 U.S.C. § 120 of International Application No. PCT/EP2021/082187, filed Nov. 18, 2021, which claims priority to GB Application No. GB 2018231.7, filed Nov. 19, 2020, under 35 U.S.C. § 119(a). Each of the above-referenced patent applications is incorporated by reference in its entirety.

### BACKGROUND

### Technical Field

The present invention relates to electric vehicle supply equipment. The electric vehicle supply equipment is suitable for providing an electrical supply for connection to an electric vehicle, typically for supplying electrical power to charge a battery of the electric vehicle.

### Background

There is a growing market for electric vehicle supply equipment for providing an electrical supply for connection to one or more electric vehicles. The electric vehicle supply equipment is typically configured for connection to a source of electrical power such as a single or three phase mains supply or a generator, which may be situated inside or outside a building. It may be required to install the electric vehicle supply equipment in a wide variety of situations in which there may be a wide variation in characteristics of the source of electrical power and in particular regarding the arrangements for connecting the equipment to electrical ground, also referred to as electrical earth. In each situation, it is necessary to comply with requirements for electrical safety, and it is typically required to cut off the electrical supply and an earth connection to the vehicle if the requirements are not met. Ensuring that the electrical safety requirements are complied with can be demanding and time consuming for an installer of the device and can lead to the requirement for multiple alternative versions of the electric vehicle supply equipment, or to further protection devices being required.

### SUMMARY

In accordance with a first aspect of the invention there is provided electric vehicle supply equipment having at least a first live terminal, a neutral terminal and a circuit protective conductor terminal, for connection to respective conductors of a mains supply, and a reference ground terminal for connection to a ground reference, the electric vehicle supply equipment comprising:

a supply circuit for providing a charging supply to an electric vehicle, the supply circuit comprising an isolation device controllable to disconnect the charging supply from the electric vehicle; and a test circuit configured to test one or more voltage differences between the terminals of the electric vehicle supply equipment and to cause the isolation device of the supply circuit to disconnect the charging supply from the electric vehicle if at least one voltage difference exceeds a respective voltage limit between the respective terminals, wherein the test circuit is configured to be switchable from a first test mode to at least a second test mode, the test circuit being configured, in the first test mode, to test a first voltage difference between the first live terminal and the neutral terminal, a second voltage difference between the first live terminal and the reference ground terminal and a third voltage difference between the circuit protective conductor terminal and the reference ground terminal and to disconnect the charging supply from the electric vehicle if at least one of the first, second and third voltage differences exceeds a respective voltage limit between the respective terminals, and the test circuit being configured, in the second test mode, to test the first voltage difference and to disconnect the charging supply from the electric vehicle if the first voltage difference exceeds a respective voltage limit and not to disconnect the charging supply from the electric vehicle in response to any test of the second or third voltage differences, wherein the voltage limit for the first voltage difference is configured to be greater in the first test mode than in the second test mode.

This arrangement allows a single version of the electric vehicle supply equipment to be suitable for installation in situations in which the electrical safety requirements require that the tests of either the first test mode or the second test mode are performed. Furthermore, configuring the voltage limit for the first voltage difference to be greater in the first test mode than in the second test mode may reduce the incidence of unnecessary disconnection of the charging supply from the electric vehicle in the first test mode.

In the first test mode, the test circuit may be configured to test the second voltage difference by combining a measured voltage difference between the first live terminal and the neutral terminal and a measured voltage difference between the neutral terminal and the reference ground terminal and to test the third voltage difference by combining a measured voltage difference between the circuit protective conductor terminal and the neutral terminal and a measured voltage difference between the neutral terminal and the reference ground terminal.

This arrangement allows the tests in the first mode to be performed using voltage measurements which are all referenced to the neutral terminal. Referencing all measurements to the neutral terminal allows a reduction in the complexity of the test circuit by allowing the use of a single protective isolation circuit.

The test circuit may comprise an analogue circuit referenced to the neutral terminal and a digital circuit referenced to a different terminal, typically the circuit protective conductor terminal, the analogue circuit being coupled to the digital circuit by a protective isolation circuit, wherein the analogue circuit is configured to measure: at least the voltage difference between the first live terminal and the neutral terminal; the voltage difference between the neutral terminal and the reference ground terminal; and the voltage difference between the circuit protective conductor terminal and the neutral terminal.

This arrangement provides a reduced complexity test circuit by the use of a single protective isolation circuit.

The electric vehicle supply equipment may have a second live terminal and a third live terminal, the first, second and third live terminals being for connection to a three phase mains supply,
wherein the test circuit is configured, in the first and second test modes, to test a fourth voltage difference between the second live terminal and the neutral terminal and to test a fifth voltage difference between the third live terminal and the neutral terminal.

This arrangement allows the test circuit to operate in the first and second modes using a three-phase supply.

In accordance with a second aspect of the invention there is provided electric vehicle supply equipment having at least a live terminal, a neutral terminal and a circuit protective conductor terminal for connection to respective conductors of a mains supply, and a reference ground terminal for connection to a ground reference, the electric vehicle supply equipment comprising:
a supply circuit for providing a charging supply to an electric vehicle, the supply circuit comprising an isolator device controllable to disconnect the charging supply from the electric vehicle; and
a test circuit configured to test a first voltage difference between the live terminal and the neutral terminal, a second voltage difference between the live terminal and the reference ground terminal and a third voltage difference between the circuit protection conductor terminal and the reference ground terminal, and the test circuit being configured to cause the isolator device of the supply circuit to disconnect the charging supply from the electric vehicle if at least one of the first, second and third voltage differences exceeds a respective voltage limit between the respective terminals,
wherein the test circuit is configured to test the second voltage difference by combining a measured voltage difference between the live terminal and the neutral terminal and a measured voltage difference between the neutral terminal and the reference ground terminal, and to test the third voltage difference by combining a measured a voltage difference between the circuit protective conductor terminal and the neutral terminal and a measured voltage difference between the neutral terminal and the reference ground terminal.

This arrangement allows the tests in the first mode to be performed using voltage measurements which are all referenced to the neutral terminal. Referencing all measurements to the neutral terminal allows a reduction in the complexity of the test circuit by allowing the use of a single protective isolation circuit.

The test circuit may comprise an analogue circuit referenced to the neutral terminal and a digital circuit referenced to the circuit protective conductor terminal, the analogue circuit being connected to the digital circuit by a protective isolation circuit, wherein the analogue circuit is configured to measure at least the voltage difference between the first live terminal and the neutral terminal, to measure the voltage difference between the neutral terminal and the reference ground terminal, and to measure the voltage difference between the circuit protective conductor terminal and the neutral terminal.

This arrangement provides a reduced complexity test circuit by the use of a single protective isolation circuit.

The electric vehicle supply equipment may have a second live terminal and a third live terminal, the first, second and third live terminals being for connection to a three phase mains supply,
wherein the test circuit is configured to test a fourth voltage difference between the second live terminal and the neutral terminal and to test a fifth voltage difference between the third live terminal and the neutral terminal.

This arrangement allows the test circuit to operate in the first and second modes using a three-phase supply.

Further features and advantages of the invention will become apparent from the following description of examples of the invention, which is made with reference to the accompanying drawings.

### BRIEF DESCRIPTION OF THE DRAWINGS

In order that the present invention may be more readily understood, examples of the invention will now be described, with reference to the accompanying drawings, in which:

FIG. 1 is a schematic diagram showing electric vehicle supply equipment installed with an earth reference electrode;

FIG. 2 is a schematic diagram showing electric vehicle supply equipment installed without an earth reference electrode;

FIG. 3 is a schematic diagram showing electric vehicle supply equipment for use with a single phase supply;

FIG. 4 is a schematic diagram showing electric vehicle supply equipment for use with a three phase supply; and

FIG. 5 is a schematic diagram showing use of a protective isolation circuit between analogue and digital circuits in electric vehicle supply equipment.

### DETAILED DESCRIPTION

Examples of the invention are described in the context of electric vehicle supply equipment (EVSE) for use at a domestic property powered by a mains electricity supply, from an electricity substation, used to provide an electricity supply to an electric vehicle for the purposes of charging the electric vehicle. However, the examples are not limited to this context, for example the EVSE may be for use at business or industrial premises or any other location and may be installed inside or outside a building. The electricity supply may be provided by a generator or other power source. Furthermore, examples may apply to other electricity supply equipment, for example to provide an electricity supply to other outdoor electrical vehicles such as caravans and other items such as home batteries, air conditioners and heat pumps.

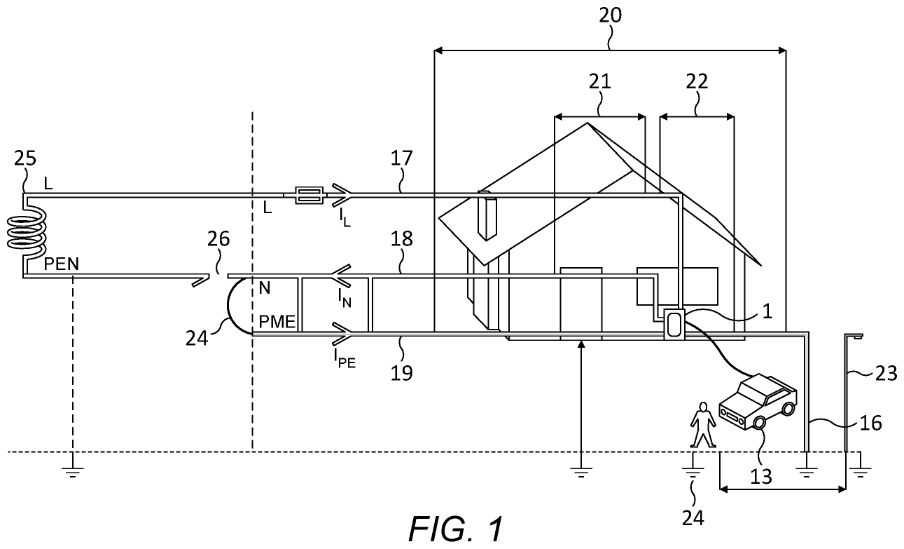

FIG. 1 shows an EVSE 1 installed with a connection to a ground reference 16 in addition to connections to a live 17, a neutral 18 and a circuit protection conductor (CPC) 19. The CPC may be connected 24 to the neutral 18 at the premises where the EVSE 1 is installed as shown, or may be connected to the neutral at an electricity substation 25 supplying mains electricity to the premises. The CPC 19 is configured to carry a fault current in a fault condition, whereas the ground reference 16 is intended as a voltage reference source. The ground reference source is typically not configured to carry a fault current and is not connected to the CPC 19. The ground reference 16 may be installed specifically for use with the EVSE 1 or may be an existing connection to ground. FIG. 1 also shows an electric vehicle 13 connected to the EVSE 1 for charging.

As shown in FIG. 1, there may be a fault 26 in the electricity supply, in this example caused by a break in the neutral connection to the electricity substation. In this case, the neutral and CPC may be caused to carry a higher voltage than the local ground around the location where the electric vehicle is being charged. This may present a safety hazard, because a person touching the electric vehicle 13 may also be able to touch a locally grounded object, such as a lamp post 23 or any other earthed object 24, and may be subjected to an electric shock. To detect a safety hazard in an installation as shown in FIG. 1, it may be required, by safety regulations or otherwise, that the EVSE 1 tests the voltage 22 between the live and the reference ground, the voltage 21 between the live and neutral, and the voltage 20 between the CPC and the reference ground, and to disconnect the supply to the electric vehicle if any one of these voltages exceeds a specified level.

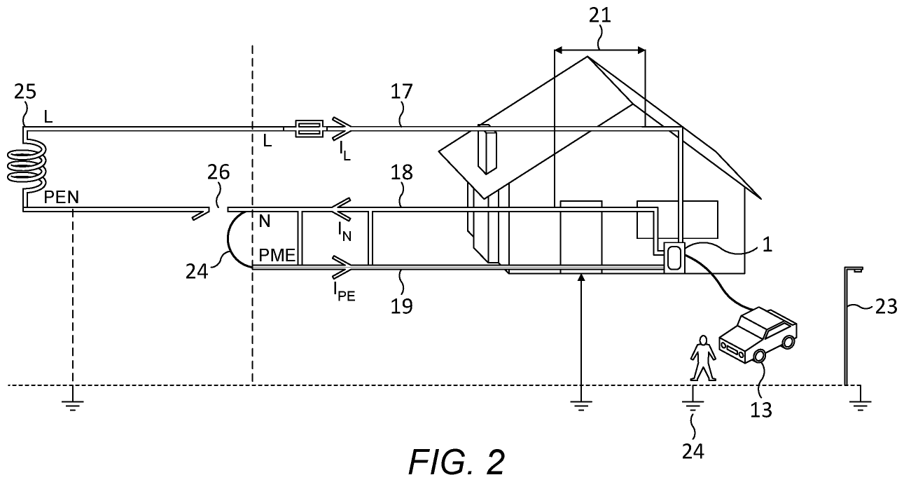

FIG. 2 shows an alternative installation to that shown in FIG. 1. In the case of example of FIG. 2, the EVSE 1 is installed without a ground reference electrode. In this case, to detect a safety hazard in an installation caused by a break in the connection of the CPC to the substation, it may be required, by safety regulations or otherwise, that the EVSE 1 tests the voltage 21 between the live and neutral. In this case, as there is no reference ground, there can be no requirement to test a voltage between the live and a reference ground or a voltage between the CPC and a reference ground. In this case it may be required to disconnect the supply to the electric vehicle if the voltage 21 between the live 17 and neutral 18 exceeds a specified level.

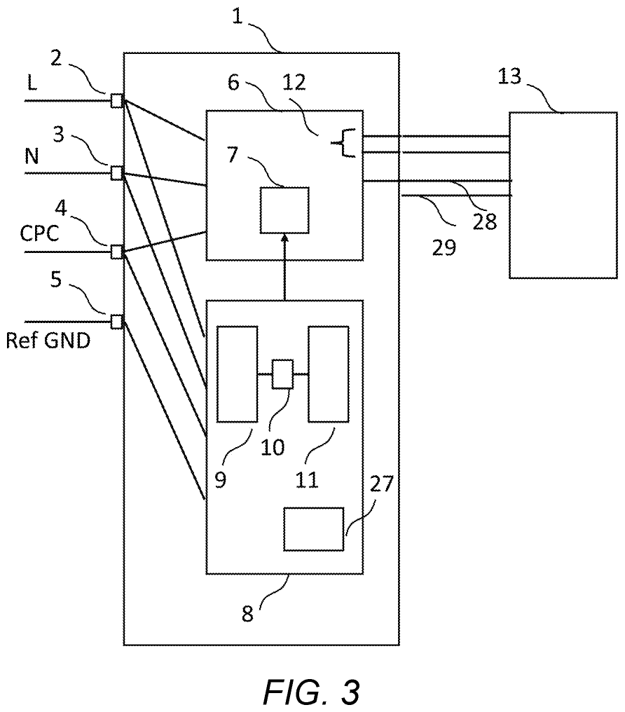

FIG. 3 is shows an example of EVSE 1 which may be used for installation in either the arrangement of FIG. 1 with a reference ground or the arrangement of FIG. 2 without a reference ground. The EVSE 1 has a test circuit 8 which is switchable between a first test mode for testing the voltages required if a ground reference is used, as, for example, is shown in FIG. 1, and a second test mode for testing the voltages required if a ground reference not used, as, for example, is shown in FIG. 2. The switching between modes may be by a switch 27. The switch may be mechanical, electromechanical, or realised via software control. The switch may be operated by an installer, controlled automatically in response to suitable test circuitry or software, or may be remotely controlled, for example, via an Internet connection.

As shown in FIG. 3, EVSE 1 in this example has a first live terminal 2, a neutral terminal 3 and a CPC terminal 4, for connection to respective conductors of a mains supply, and a reference ground terminal 5 for connection to a ground reference. The terminals may be standard electrical terminals suitable for connection to an electrical mains supply, typically an alternating current (AC) mains supply, for example by grub screw, crimping, a clamp or any other appropriate connection method. In the example of FIG. 3, a single-phase mains supply is shown, having a single live terminal 2.

The EVSE 1 comprises a supply circuit 6 for providing a charging supply to an electric vehicle 13, the supply circuit 6 comprising an isolation device 7 controllable to disconnect or decouple the charging supply from the electric vehicle 13. The isolation device 7 according to this example may be a relay. The supply circuit 6 may comprise a connection from the live terminal 2 and neutral terminal 3 to the respective outputs 12 of the charging supply 6 for connection to the electric vehicle 13, so that the charging supply for the electric vehicle is also AC. The connections from the supply circuit to the electric vehicle typically include an earth connection 28, connected to the CPC terminal 4 and a communication connection 29 to carry signals exchanged between the EVSE 1 and the electric vehicle 13.

A test circuit 8, which may be implemented by one or more digital processors, is configured to test one or more voltage differences between the terminals of the EVSE 1 and to cause the isolation device 7 of the supply circuit to disconnect the charging supply 12 from the electric vehicle 13 if at least one voltage difference exceeds a respective voltage limit between the respective terminals. The test circuit 8 is configured to be switchable by switch 27 from a first test mode to at least a second test mode, in the present example, by an electromechanical switch. The test circuit 8 is configured, in the first test mode, to test a first voltage difference between the first live terminal 2 and the neutral terminal 3, a second voltage difference between the first live terminal 2 and the reference ground terminal 5 and a third voltage difference between the CPC terminal 4 and the reference ground terminal 5. In some examples, the testing may be by the combination of measurements between different pairs of terminals. In the second test mode, the test circuit 8 is configured to test the first voltage difference, that is to say the voltage difference between the live and neutral terminals, and not to test the second or third voltage differences. The circuitry for measuring the voltages between pairs of terminals other than the neutral and live pair may optionally be active in the second mode, but the outcome of any measurements is not used to decide whether the charging supply 12 to the electric vehicle will be disconnected.

The inventors have found that it may be beneficial to set a higher voltage limit or threshold for the live to neutral voltage for the first test mode than for the voltage limit or threshold for the live to neutral voltage for the second test mode. The higher voltage limit may meet the safety requirements in an installation with a ground reference, as is the case for installations for which the first test mode is appropriate. However, in installations for which the second test mode is appropriate, the higher voltage limit may not meet the safety requirements, in particular for some cases of an installation without a ground reference. Typically, the first test mode may be selected if there is a risk of simultaneous contact with the electric vehicle and an earthed object, and the second test mode may be selected if there is not a risk of simultaneous contact with the electric vehicle and an earthed object. Both the first test mode and the second test mode provide protection against the risk that a protective earth/neutral connection is broken 26 in the mains supply to the premises where the EVSE is installed, as shown in FIGS. 1 and 2.

The higher voltage limit has the advantage of reducing the probability of spurious disconnection of the supply to the electric vehicle. By changing the limit for the live to neutral voltage when changing from one test mode to the other, installation is simplified and operation of the installed EVSE is improved.

In the example, in the first test mode, the test circuit is configured to test the second voltage difference, that is to say the difference between the live terminal 2 and the reference ground terminal 5, by combining, typically by adding, a measured voltage difference between the first live terminal 2 and the neutral terminal 3 and a measured voltage difference between the neutral terminal 3 and the reference ground terminal 5. Also, the third voltage difference (CPC to reference ground) is tested by combining a measured voltage difference between the circuit protective conductor terminal 4 and the neutral terminal 3 and a measured voltage difference between the neutral terminal 3 and the reference ground terminal 5. This combination of measurements between two pairs of terminals to test the voltage between a single pair of terminals may be thought to have the disadvantage of potentially producing a less accurate result, for instance due to noise on the neutral conductor potentially being different for the two measurements. However, it has been found that this approach has the potentially greater benefit that each of the measurements may be referenced to the same conductor, in this case neutral terminal. This allows a circuit implementation using a single protective isolation circuit 10, which may be a transformer or, for example, an opto-isolator. The protective isolation circuit 10 is potentially costly and bulky and so it is advantageous to use one only for this purpose.

The test circuit 8, as shown in FIG. 3, comprises an analogue circuit 9 referenced to the neutral terminal 3 and a digital circuit 11 referenced to the CPC terminal 4, the analogue circuit 9 being coupled to the digital circuit 11 by the protective isolation circuit 10. The analogue circuit typically has an analogue to digital converter, and is configured to measure at least: the voltage difference between the first live terminal 2 and the neutral terminal 3; the voltage difference between the neutral terminal 3 and the reference ground terminal 5; and, the voltage difference between the CPC terminal 4 and the neutral terminal 3. The test circuit may potentially be used in an EVSE without the ability to be switched between operating modes if required.

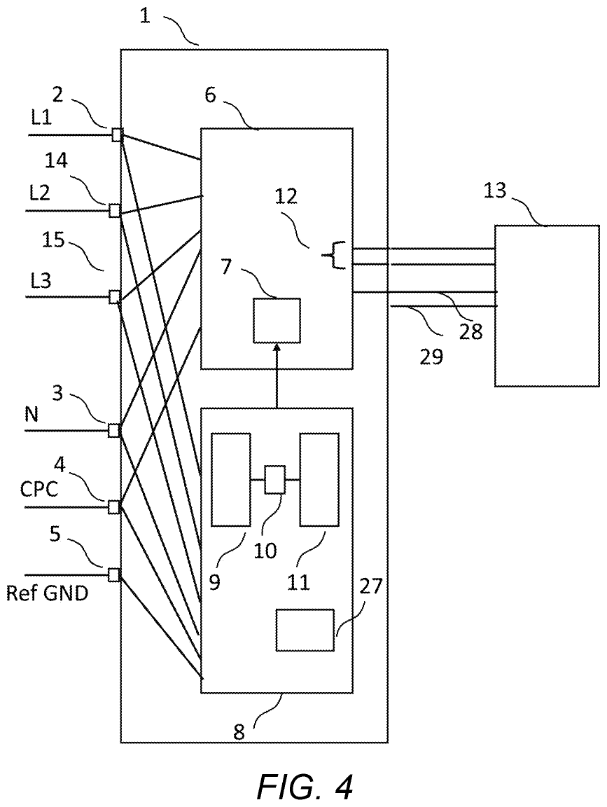

FIG. 4 shows an example of the EVSE 1, configured for use with a three-phase supply. The EVSE has a second live terminal 14, and a third live terminal 15. The first 2, second 14 and third 15 live terminals are for connection to the respective three live phases of the three-phase supply, and the neutral terminal 3 is for connection to the neutral conductor of the three-phase supply. In the case of the arrangement of FIG. 4, the test circuit is configured, in the first and second test modes, to test a fourth voltage difference between the second live terminal 14 and the neutral terminal 3 and to test a fifth voltage difference between the third live terminal 15 and the neutral terminal 3. In the case that the live-neutral voltage exceeds the specified limit for the mode for any of the three phases, the test circuit will disconnect the charging supply to the electric vehicle.

A specific example of first and second test modes for the test circuit is as follows. In the first test mode, a “L-N Trip” is set to have a trip voltage, that is to say the specified voltage difference between the live and neutral terminals, above which the charge supply 12 to the electric vehicle is disconnected, of 258V RMS in this example, for a nominally 230V mains system. This is 12% above the nominal voltage. In the example, the second test mode, the “L-N Trip” is set to have a trip voltage of 253V RMS, which is 10% above the nominal voltage. It can be seen that the voltage limit for the live to neutral voltage measurement (also referred to as the first voltage difference) is configured to be greater in the first test mode than in the second test mode. In this example, the voltage limit for the live to neutral voltage measurement is configured to be greater by 2% in the first test mode than in the second test mode. In examples, the voltage limit for the live to neutral voltage measurement may be configured to be at least 1%, at least 2%, or even at least 5% higher in the first test mode than in the second test mode. In the second mode, the voltage limit may be 5%, 7% or 10% above the nominal voltage in examples. This apparently small difference, which equates to about a 5V increase in the limit or threshold, has been found to have a significant benefit in terms of reducing unnecessary disconnections of the charge supply due to variable and/or unreliable electrical supply voltages. There may also be a lower limit set for the first voltage difference, and the supply to the electric vehicle may be disconnected if the voltage difference is less than a lower limit between the respective terminals. In the first mode, the lower limit to the voltage difference between the live and neutral terminals, below which the charge supply 12 to the electric vehicle is disconnected, may be set to 202V RMS, and in the second mode the lower limit may be set to 207V RMS. The size of the limit or threshold may be varied depending on the quality of the supply voltages in any particular supply area. In the second mode, regulations may prohibit a rising of the voltage limit, which may be allowed in the first mode. In this example, the live to reference ground voltage test in the first test mode, the “L—TT Ref trip”, has a specified limit of 258V RMS, and the CPC to reference ground voltage test “PME—TT Ref trip” has a specified limit of 30V RMS. In the second test mode, neither the live to reference ground voltage test nor the CPC to reference ground voltage test is performed.

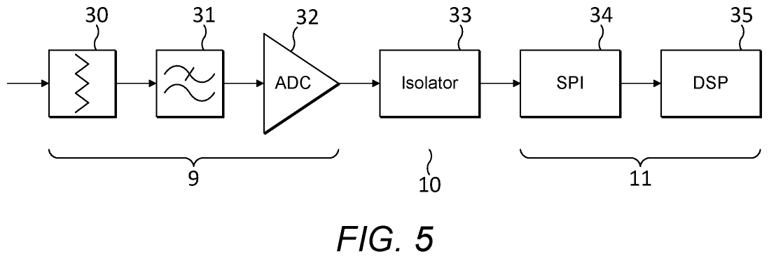

FIG. 5 is a schematic diagram showing an example of part of the test circuit 8 having a protective isolation circuit 10 between analogue circuit 9 and digital circuit 11 in the EVSE. The protective isolation circuit 10 may be implemented by a transformer or opto-isolator, for example. This allows the respective local grounds of the analogue circuit (referenced to neutral) and the digital circuit (referenced to CPC) to float relative to each other, providing benefits in terms of safety and potentially noise reduction. Connections to the live terminal live 2, the CPC terminal 4, and the reference ground terminal 5 provide respective live signals, CPC (“earth”) signals, and reference ground signals, which may be provided sequentially via a multiplexing switch. The signals are each referenced to a local analogue ground provided by the neutral terminal 3. Each signal enters the analogue circuitry 9 is attenuated by a resistor network 30. The signal is then filtered to remove frequencies higher than 100 Hz 31 before being fed into the analogue to digital converter (ADC) 32. The signals may be multiplexed into the ADC. The digital signals from ADC are sent via an isolator 33 to the serial microcontroller SPI port 34. The digital signals are provided to a Digital Signal Processing functional block 35 which uses a Fast Fourier Transform (FFT), which provides the magnitude of AC signals at mains frequency. The microcontroller monitors the Live, Earth of the incoming mains and the reference electrode connection if one is available. In an example, if any of the voltages fall outside of a permissible range for longer than 4 seconds, then the mains will be disconnected, after not more than 5 seconds after the voltage falls, from the vehicle or the mains voltage will be inhibited from being connected to the vehicle until the event has passed. If the vehicle is connected and charging, after 2 seconds of continuous fault a control pilot signal to the vehicle will indicate the EVSE will no longer be supplying charge current and attempt to stop the vehicle charging. Should the supply return to normal before the 4 seconds period then the EVSE must observe 10 seconds of continuous correct supply conditions before the vehicle is permitted to charge again.

It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the invention, which is defined in the accompanying claims.

1. Electric vehicle supply equipment having at least a first live terminal, a neutral terminal and a circuit protective conductor terminal, for connection to respective conductors of a mains supply, and a reference ground terminal for connection to a ground reference, the electric vehicle supply equipment comprising:
a supply circuit for providing a charging supply to an electric vehicle, the supply circuit comprising an isolation device controllable to disconnect the charging supply from the electric vehicle; and
a test circuit configured to test one or more voltage differences between the terminals of the electric vehicle supply equipment and to cause the isolation device of the supply circuit to disconnect the charging supply from the electric vehicle if at least one voltage difference exceeds a respective voltage limit between the respective terminals,
wherein the test circuit is configured to be switchable from a first test mode to at least a second test mode,
the test circuit being configured, in the first test mode, to test a first voltage difference between the first live terminal and the neutral terminal, a second voltage difference between the first live terminal and the reference ground terminal and a third voltage difference between the circuit protective conductor terminal and the reference ground terminal and to disconnect the charging supply from the electric vehicle if at least one of the first, second and third voltage differences exceeds a respective voltage limit between the respective terminals, and
the test circuit being configured, in the second test mode, to test the first voltage difference and to disconnect the charging supply from the electric vehicle if the first voltage difference exceeds a respective voltage limit and not to disconnect the charging supply from the electric vehicle in response to any test of the second or third voltage differences,
wherein the voltage limit for the first voltage difference is configured to be greater in the first test mode than in the second test mode.

2. The electric vehicle supply equipment of claim 1, wherein, in the first test mode, the test circuit is configured to test the second voltage difference by combining a measured voltage difference between the first live terminal and the neutral terminal and a measured voltage difference between the neutral terminal and the reference ground terminal and to test the third voltage difference by combining a measured voltage difference between the circuit protective conductor terminal and the neutral terminal and a measured voltage difference between the neutral terminal and the reference ground terminal.

3. The electric vehicle supply equipment of claim 2, wherein the test circuit comprises an analogue circuit referenced to the neutral terminal and a digital circuit referenced to the circuit protective conductor terminal, the analogue circuit being coupled to the digital circuit by a protective isolation circuit, wherein the analogue circuit is configured to measure: at least the voltage difference between the first live terminal and the neutral terminal; the voltage difference between the neutral terminal and the reference ground terminal; and the voltage difference between the circuit protective conductor terminal and the neutral terminal.

4. The electric vehicle supply equipment of claim 1, having a second live terminal and a third live terminal, the first, second and third live terminals being for connection to a three phase mains supply,
wherein the test circuit is configured, in the first and second test modes, to test a fourth voltage difference between the second live terminal and the neutral terminal and to test a fifth voltage difference between the third live terminal and the neutral terminal.

5. Electric vehicle supply equipment having at least a live terminal, a neutral terminal and a circuit protective conductor terminal for connection to respective conductors of a mains supply, and a reference ground terminal for connection to a ground reference, the electric vehicle supply equipment comprising:
a supply circuit for providing a charging supply to an electric vehicle, the supply circuit comprising an isolator device controllable to disconnect the charging supply from the electric vehicle; and
a test circuit configured to test a first voltage difference between the live terminal and the neutral terminal, a second voltage difference between the live terminal and the reference ground terminal and a third voltage difference between the circuit protection conductor terminal and the reference ground terminal, and the test circuit being configured to cause the isolator device of the supply circuit to disconnect the charging supply from the electric vehicle if at least one of the first, second and third voltage differences exceeds a respective voltage limit between the respective terminals,
wherein the test circuit is configured to test the second voltage difference by combining a measured voltage difference between the live terminal and the neutral terminal and a measured voltage difference between the neutral terminal and the reference ground terminal, and to test the third voltage difference by combining a measured a voltage difference between the circuit protective conductor terminal and the neutral terminal and a measured voltage difference between the neutral terminal and the reference ground terminal.

6. The electric vehicle supply equipment of claim 5, wherein the test circuit comprises an analogue circuit referenced to the neutral terminal and a digital circuit referenced to the circuit protective conductor terminal, the analogue circuit being connected to the digital circuit by a protective isolation circuit, wherein the analogue circuit is configured to measure at least the voltage difference between the first live terminal and the neutral terminal, to measure the voltage difference between the neutral terminal and the reference ground terminal, and to measure the voltage difference between the circuit protective conductor terminal and the neutral terminal.

7. The electric vehicle supply equipment of claim 5, the electric vehicle supply equipment having a second live terminal and a third live terminal, the first, second and third live terminals being for connection to a three phase mains supply,
wherein the test circuit is configured to test a fourth voltage difference between the second live terminal and the neutral terminal and to test a fifth voltage difference between the third live terminal and the neutral terminal.
